(19) United States
(12) Patent Application Publication
(10) Pub. No.: US 2017/0374760 A1
(43) Pub. Date: Dec. 28, 2017

(54) FAN CONTROL BASED ON MEASURED HEAT FLUX

(71) Applicant: HEWLETT-PACKARD DEVELOPMENT COMPANY, L.P., HOUSTON, TX (US)

(72) Inventor: CHUN-CHIEH CHEN, TAIPEI CITY (TW)

(21) Appl. No.: 15/539,796

(22) PCT Filed: Jan. 28, 2015
(86) PCT No.: PCT/US15/13251

§ 371 Date: Jun. 26, 2017

(51) Int. Cl. H05K 7/20; G06F 1/20

(52) U.S. Cl. CPC H05K 7/20209; G06F 1/206

(57) ABSTRACT

Example implementations relate to measuring a heat flux of a plurality of vents of a device by at least one heat flux sensor and generating a fan control signal to control at least one fan of the device, based on the measured heat flux.

### BACKGROUND

An electronic device may include components, such as processors, that generate heat within the device. An electronic device may include chassis vents to dissipate generated heat. An electronic device may also include fans to dissipate generated heat.

### BRIEF DESCRIPTION OF THE DRAWINGS

Various examples will be described below with reference to the following figures.

FIG. 1 is a block diagram of an example device for generating a fan control signal according to an implementation.

FIG. 2 is a block diagram of an example device for generating a fan control signal according to another implementation.

FIG. 3A is a block diagram of the example device of FIG. 2 in a first orientation.

FIG. 3B is a block diagram of the example device of FIG. 2 in a second orientation.

FIG. 3C is a block diagram of the example device of FIG. 2 illustrating a user holding position.

FIG. 4 is a flow diagram of an example method for generating a fan control signal according to an implementation.

FIG. 5 is a flow diagram of an example method for generating a fan control signal according to another implementation.

FIG. 6 is a block diagram of an example computing device for generating a fan control signal that includes a machine-readable medium encoded with instructions according to an implementation.

FIG. 7 is a block diagram of an example computing device for generating a fan control signal that includes a machine-readable medium encoded with instructions according to another implementation.

### DETAILED DESCRIPTION

Electronic devices may include ventilation systems having chassis vents and/or fans to dissipate heat generated by components within the devices, such as processors. Many electronic devices, such as tablet devices, convertible laptop devices, handheld devices, and the like may be operated in multiple orientations. Additionally, a user may hold different parts of the device (e.g., for different orientations or for comfort), which may block the vents of the device. Moreover, changes in the environment, such as a decrease in ambient temperature, may increase or decrease the need for ventilation of the device. In the foregoing conditions, a ventilation system designed to dissipate heat in a predetermined fixed manner may become less efficient.

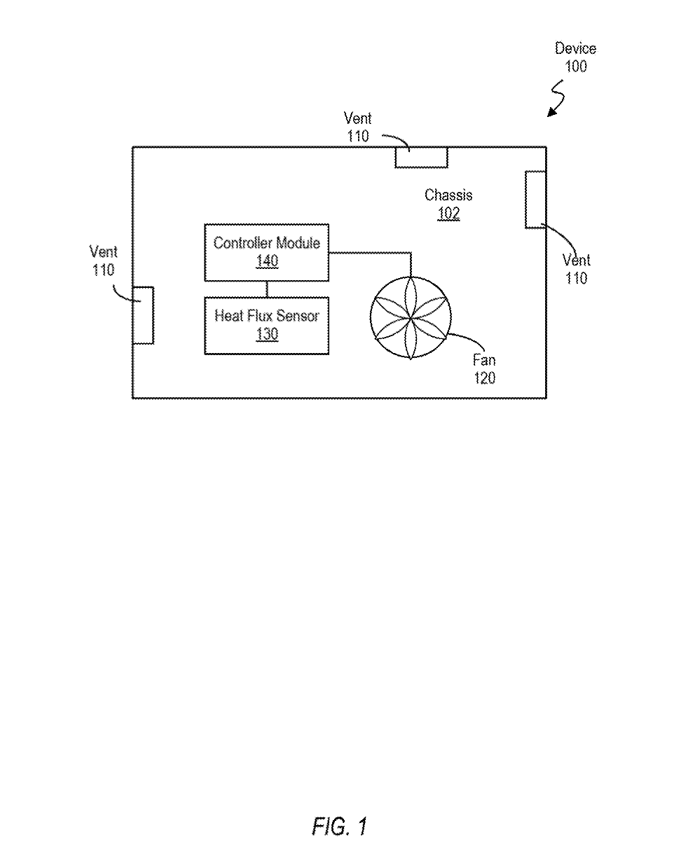

Referring now to the figures, FIG. 1 is a block diagram of an example device 100. The device 100 includes a chassis 102 that has a plurality of vents 110 (also referred to as the vents 110 or the chassis vents 110, or referred to singularly as a vent 110). The device 100 may also include a fan 120, a heat flux sensor 130, and a controller module 140. In some implementations, the chassis 102 may be a housing (or enclosure) that encloses components of the device 100, such as a processor, memory, a disk drive, or the like, which may generate heat during operation of the device 100. In some implementations, the vents 110 are openings in the chassis 102 that allow air to flow in and/or out of the chassis 102. For example, the device 100 may be or may form part of a laptop computer, a desktop computer, a workstation, a mobile phone, a tablet computing device, a wearable electronic device, a gaming device, and/or other electronic device.

In some implementations, the fan 120 may move air (in other words, may produce air flow) through at least one of the vents 110. More particularly, the fan 120 may draw air in to the chassis 102 through at least one of the vents 110 and/or may blow air out of the chassis 102 through at least one of the vents, depending, for example, on an air flow direction attribute of the fan 120 (e.g., based on a clockwise or counterclockwise rotation of the fan 120). Additionally, the fan 120 may move air at an air flow rate in a range of air flow rates, depending on a fan speed attribute of the fan 120. In some implementations, the fan may be in an air flow path of a vent 110 defined at least in part by a baffle, an air diverter, a channel, and/or other air flow-directing structures. In some implementations, the air flow path may be opened or closed (including varying states in between opened and closed) by a damper included in the air flow path and controlled by controller module 140. In some implementations, the device 100 may move air in different air flow directions and/or different air flow rates through individual vents of the plurality of vents, by virtue of independently-controlled dampers in air flow paths between the fan 120 and individual vents. In some implementations, the fan 120 may be a plurality of fans, and each vent of the plurality of vents 110 is in an air flow path of at least one fan of the plurality of fans.

The heat flux sensor 130 may be to measure a heat flux (e.g., in W/m²) of the plurality of vents 110, or, in other words, the rate of heat energy transfer through the plurality of vents 110. Generally, air inside of the chassis 102 may be warmer than air outside of the chassis 102, by virtue of, for example, heat generated by components of the device 100. Heat may transfer out of the chassis 102 through a vent 110 by natural convective flow (i.e., lower density heated air inside the chassis 102 may move due to buoyancy) or by fan-blown air. The transfer of heat through a vent 110 may present a measurable heat flux at that vent 110. Similarly, cooler outside air drawn into the chassis 102 through a vent 110 by the fan 120 also may present a measurable heat flux of that vent 110.

In some implementations, the heat flux sensor 130 may be positioned in a vicinity of at least one of the vents 110 to measure the heat flux of a vent 110. For example, in some implementations, the heat flux sensor 130 may be disposed in an air flow path between the fan 120 and at least one of the vents 110. In some implementations, the heat flux sensor 130 may be integrated into at least one of the vents 110.

A module, as referred to herein (such as the controller module 140), can include a set of instructions encoded on a machine-readable storage medium and executable by a processor. Additionally or alternatively, a module may include a hardware device comprising electronic circuitry for implementing functionality described herein.

In some implementations, the controller module 140 may be communicatively coupled (e.g., by wires) to the fan 120 and/or the heat flux sensor 130. For example, in some implementations, the controller module 140 may periodically or continuously receive (or retrieve) from the heat flux sensor 130 a heat flux measurement of the plurality of vents 110. In some implementations, the controller module 140 may control at least one of a speed or an air flow direction of the fan 120 according to a fan control signal. For example, in some implementations, the controller module 140 may transmit a fan control signal to the fan 120. In some implementations, where the fan 120 is one of a plurality of fans (as described above), the controller module 140 may control each fan of the plurality of fans independently.

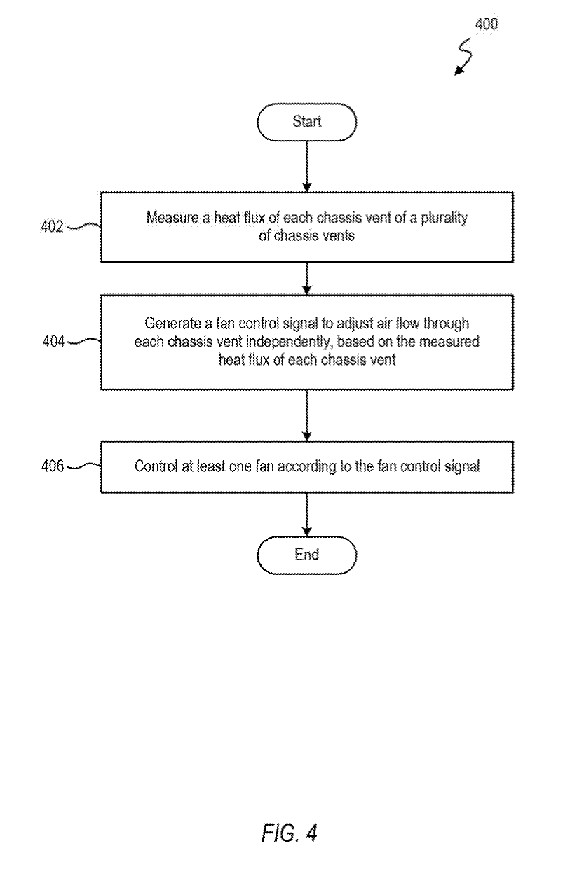

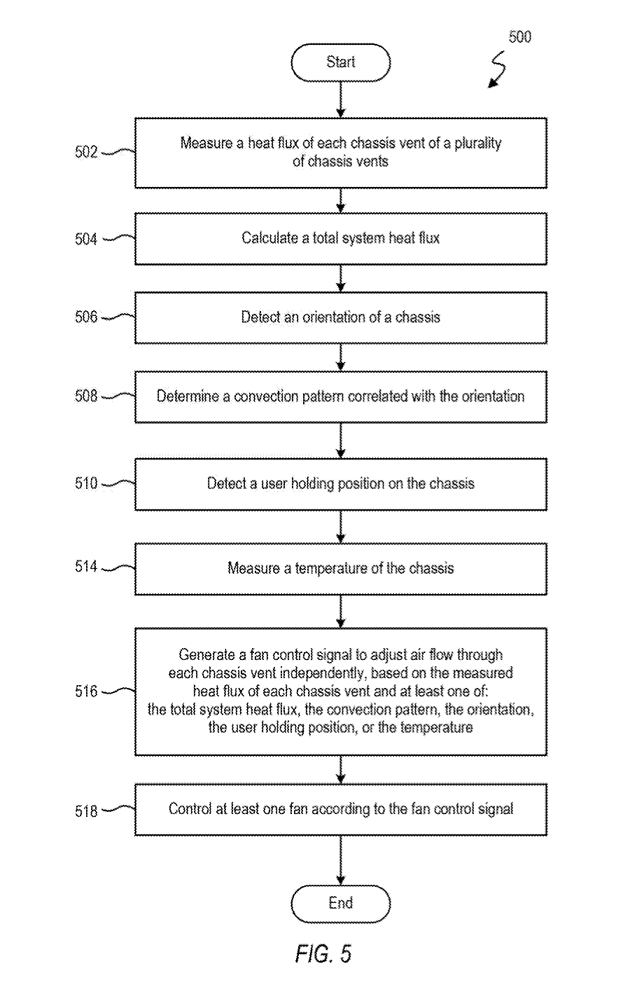

In some implementations, the controller module 140 may generate a fan control signal, based on (in response to) the measured heat flux of the plurality of vents 110 (e.g., as measured by and received from the heat flux sensor 130). The fan control signal may be, for example, a signal that controls at least one of the fan speed or the air flow direction of the fan 120 to adjust an air flow through the vents 110. In some implementations, the controller module 140 may include and use optimization logic (e.g., iterative search logic) and/or closed-loop control logic (also referred to as feedback control logic, such as, e.g., PID control, fuzzy logic, and the like) to generate a fan control signal that, for example, optimizes (or maximizes) the heat flux measured by the heat flux sensor 130 or maintains the measured heat flux sensor 130 at a target heat flux (i.e., a set point, such as a historical value of measured heat flux, an optimized heat flux, or another predetermined value), as described further herein below with respect to method 400 of FIG. 4 and method 500 of FIG. 5. In some implementations, the optimization logic and/or the closed-loop control logic may address both single-variable and multi-variable systems.

In some implementations, the controller module 140 may include a power saving mode that generates a fan control signal to decrease the fan speed of the fan 120 (including possibly a full stop of the fan 120) when the measured heat flux of the plurality of the vents 110 is higher than a target heat flux.

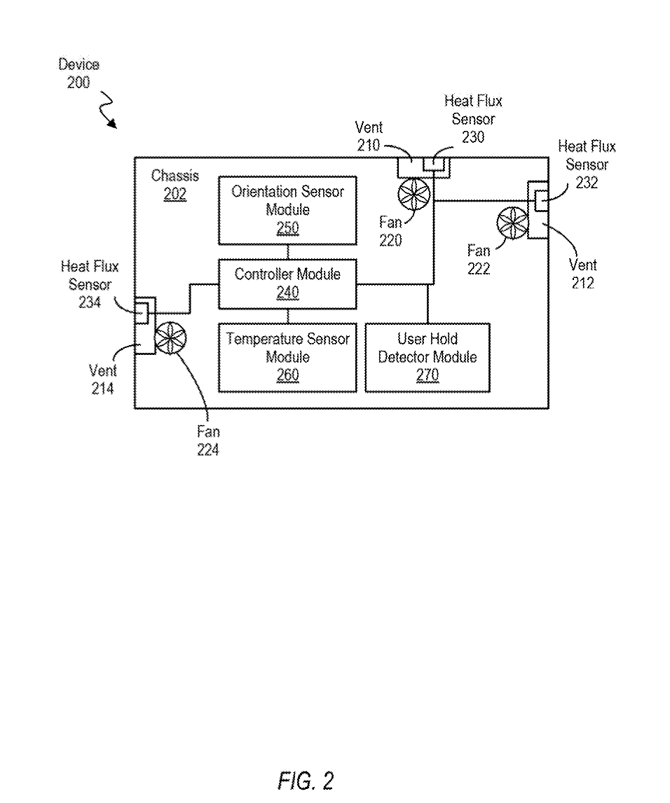

FIG. 2 is a block diagram of an example device 200. As with device 100, the device 200 may be or may form part of a laptop computer, a desktop computer, a workstation, a mobile phone, a tablet computing device, a wearable electronic device, a gaming device and/or other electronic device. The device 200 includes a chassis 202 that has a plurality of vents, such as the vents 210, 212, 214 (also referred to herein as the vents 210, 212, 214 or the chassis vents 210, 212, 214). The chassis 202 may be analogous in many respects to the chassis 102. The device 200 also may include a plurality of fans 220, 222, 224, a plurality of heat flux sensors 230, 232, 234, and a controller module 240. In some implementations, the device 200 also includes an orientation sensor module 250 to detect an orientation of the device 200 and/or the chassis 202. In some implementations, the device 200 also includes a temperature sensor module 260 to measure a temperature of the device 200. In some implementations, the device 200 also includes a user hold detector module 270 to detect a user holding position on the device 200. In some implementations, the device 200 may include the heat flux sensors 230, 232, 234 and at least one of the orientation sensor module 250, the temperature sensor module 260, or the user hold detector module 270. The foregoing features of the device 200 will now be described in turn.

Each vent 210, 212, 214 may be analogous in many respects to the vents 110. In some implementations, each vent 210, 212, 214 may be in an air flow path of at least one fan of the plurality of fans 214, 224, 234 (in other words, it may be understood that air flow may be directed from the at least one fan to a vent in the air flow path). In some implementations, each vent 210, 212, 214 is in an air flow path of a respective fan 210, 222, 224 on a one-to-one basis (for example, in the example device 200 of FIG. 2, vent 210 is in an air flow path of the fan 220, vent 212 is in an air flow path of the fan 222, and a vent 214 is in an air flow path of the fan 224). In some implementations, the fan 220, 222, or 224 is adjacent to, attached to, or disposed on a respective vent 210, 212, or 214. In some implementations, the air flow path may be defined at least in part by a baffle, an air diverter, a channel, and/or other air flow-directing structures.

Each fan 220, 222, 224 may be analogous in many respects to the fan 120 (for example, the fan 120 may be one of the plurality of fans 220, 222, 224). In some implementations, each fan 220, 222, 224 may be communicatively coupled to the controller module 240 (coupling not shown on FIG. 2, for legibility) and may be controlled independently by the controller module 240.

Each heat flux sensor 230, 232, 234 may be analogous in many respects to the heat flux sensor 130 (for example, the heat flux sensor 130 may be one of the plurality of heat flux sensors 230, 232, 234). In some implementations, at least one heat flux sensor of the plurality of heat flux sensors 230, 232, 234 is disposed at each vent of the plurality of vents 210, 212, 214, so that the plurality of heat flux sensors 230, 232, 234 measures a heat flux of each vent 210, 212, 214. For example, a heat flux sensor 230, 232, 234 may be positioned in the path of air flow through each vent 210, 212, 214. In some implementations, each heat flux sensor 230, 232, 234 is disposed at a respective vent 210, 212, 214 on a one-to-one basis (for example, in the example device 200 of FIG. 2, heat flux sensor 230 is disposed at vent 210, heat flux sensor 232 is disposed at vent 212, and heat flux sensor 234 is disposed at vent 214).

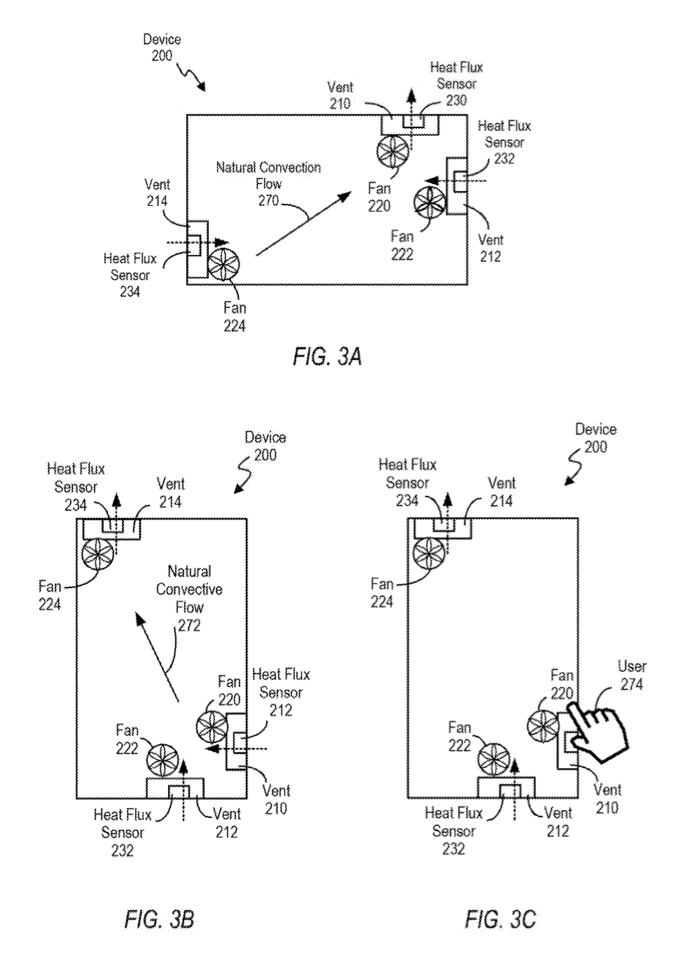

The orientation sensor module 250 may be to detect the orientation of the chassis 202 and/or the device 200. In some implementations, the orientation sensor module 250 may include an accelerometer, a magnetometer, a gyroscope, and/or the like. In some implementations, the device 200 may be operated by a user in more than one orientation. In some implementations, the orientation sensor module 250 may detect a landscape orientation (e.g., FIG. 3A) or a portrait orientation (e.g., FIG. 3B). In some implementations, the orientation sensor module 250 may detect angular orientation of the in three dimensions. By virtue of the position of the vents 210, 212, 214 changing with the orientation of the device 200 and/or the chassis 202, the natural convection flow of air inside the chassis 202 may be different for various orientations of the device 200, as illustrated, for example, in FIGS. 3A and 3B. Moreover, the direction of air flow through a vent 210, 212, or 214 may be different for different orientations of the device 200 (example air flows through the vents in FIGS. 3A and 3B are illustrated as dotted arrows). For example, in the landscape orientation illustrated in FIG. 3A, air flows out of vent 210 owing to natural convective flow 270, while in the portrait orientation illustrated in FIG. 3B, air flows in through vent 210 owing to natural convective flow 272. In some implementations, the controller module 204 may use information about the natural convective flow, based on (i.e., inferred from) the orientation of the chassis 200, to generate the fan control signal, as will be described further herein below.

The temperature sensor module 260 may be to measure a temperature of the chassis 202 and/or the device 200. For example, the temperature sensor module 260 may be a thermistor, a thermocouple, or the like. In some implementations, the temperature sensor module 260 may be disposed inside the chassis 202 on or near a component of the device 200, the performance of which may be temperature sensitive (e.g., a processor). In some implementations, the controller module 240 may use the temperature to generate the fan control signal, as will be described further herein below.

The user hold detector module 270 may be to detect a user holding position. In some implementations, the user hold detector module 270 may include a capacitive touch sensor, a resistive touch sensor, an infrared sensor, a pressure sensor, and/or the like in a vicinity (or in other words, a proximity) of each of the vents 210, 212, 214. In some implementations, the user hold detector module 270 may detect if a user is holding the device 200 at any of the vents 210, 212, 214, and may output the identity of that/those vent(s) to the controller module 240. For example, in the illustration of FIG. 3C, the user hold detector module 270 may detect the user holding position 274 to be in the vicinity of the vent 210, which may result in a blockage and/or decrease of air flow through that vent. In some implementations, a vicinity (or proximity) of a vent may be a distance that impairs air flow and/or ventilation through that vent, such as, for example, a distance in the range from zero to five centimeters from the vent. By virtue of the user hold detector module 270, the controller module 240 may use information about possible or partial blockages of the vents 210, 212, 214 to generate the fan control signal in some implementations, as will be described further herein below.

The controller module 240 may be similar in many respects to the controller module 140. In some implementations, the controller module 240 may be communicatively coupled to the fans 214, 224, 234, the heat flux sensors 212, 222, 232, the orientation sensor module 250, the temperature sensor module 260, and/or the user hold detector module 270. The controller module 240 may be to generate a fan control signal. In some implementations, the fan control signal generated by the controller module 240 includes signals to control each fan of the plurality of fans 214, 224, 234 independently, and more particularly, to control a fan speed and/or an air flow direction of each fan 214, 224, 234. In some implementations, the controller module 240 may include single-variable and/or multi-variable optimization logic. Additionally or alternatively, the controller module 240 may include single-variable and/or multi-variable closed-loop control logic.

In some implementations, the controller module 240 may generate the fan control signal based on the measured heat flux of each vent 210, 212, 214, as measured by the plurality of heat flux sensors 212, 222, 232. For example, the controller module 240 may use optimization logic and/or feedback logic to determine the fan speed and/or the air flow direction (collectively the fan control signal) at each fan 214, 224, 234 independently to maximize the measured heat flux of a respective vent 210, 212, 214 and/or to maintain the measured heat flux of a respective vent 210, 212, 214 at a set point.

In some implementations, the controller module 240 may generate the fan control signal further based on at least one of a total system heat flux (which may be, for example, the sum of the measured heat flux of each heat flux sensors 212, 222, 232), the orientation, the temperature, or the user holding position, as will be described further herein with respect to method 600.

For example, the orientation of the chassis 202 may provide the controller module 240 with initial settings of fan speed and/or air flow direction for the optimization logic and/or the closed-loop control logic that account for natural convective flow. As another example, the controller module 240 may generate a fan control signal to increase the fan speed of a fan 214, 224, or 234 when the measured heat flux of the plurality of vents 210, 212, 214 is lower than a target heat flux and the detected user holding position is outside a proximity of the plurality of vents 210, 212, 214.

In some implementations, the controller module 240 occasionally, periodically, or continuously receives (or retrieves) the user holding position of the device from the user hold detector module 270, and the controller module 240 may generate the fan control signal further based on the user holding position, in an example manner described below with respect to method 500.

In some implementations, the controller module 240 may generate the fan control signal based on the measured heat flux of each vent 210, 212, 214 and two or more of the total system heat flux, the orientation, the temperature, or the user holding position.

FIG. 4 is a flow diagram of a method 400 for generating a fan control signal according to an example implementation. In some implementations, the method 400 may be implemented, at least in part, in the form of executable instructions stored on a machine-readable medium and/or in the form of electronic circuitry. In some implementations, the steps of method 400 may be executed substantially concurrently or in a different order than shown in FIG. 4.

In some implementations, method 400 may include more or less steps than are shown in FIG. 4. In some implementations, one or more of the steps of method 400 may, at certain times, be ongoing and/or may repeat. Although execution of the method 400 is described below with reference to system 200, it should be understood that at least portions of method 400 may be performed by any other suitable device or system, such as, for example, the system 100 of FIG. 1.

The method 400 starts, and at block 402, at least one heat flux sensor 230, 232, 234 measures a heat flux of a plurality of chassis vents 210, 212, 214, and more particularly, a heat flux of each chassis vent of the plurality of chassis vents 210, 212, 214. In some implementations, the heat flux of each chassis vent 210, 212, 214 is measured by a respective heat flux sensor of a plurality of heat flux sensors 230, 232, 234. By adjusting the air flow, the fans 214, 224, 234 can affect the measured heat flux of a chassis vent 210, 212, 214.

At block 404, the controller module 240 generates a fan control signal to adjust air flow through each chassis vent 210, 212, 214 independently based on the measured heat flux of each chassis vent 210, 212, 214. In some implementations, the fan control signal may be to control a fan speed and/or an air flow direction of each fan 214, 224, 234 independently (or of at least one fan) so as to produce air flow through each chassis vent 220, 222, 224 independently.

In some implementations, the fan control signal may be to independently control dampers in air flow paths of respective chassis vents 220, 222, 224 may be controlled by the fan control signal, so as to adjust air flow through each chassis vent 220, 222, 224 independently.

In some implementations, the controller module 240 generates the fan control signal to adjust air flow at block 404 using optimization logic and/or closed-loop control logic in order to achieve (or attempt to achieve) an objective.

For example, in some implementations, the objective may be to maximize the measured heat flux of each chassis vent 210, 212, 214, by adjusting air flow through the vents. In some implementations, the objective may be to maximize the heat flux of each chassis vent 210, 212, 214 and simultaneously to minimize a total power usage of the fans 214, 224, 234.

In some implementations, the objective may be to maintain the measured heat flux of each chassis vent 210, 212, 214 at or above a target heat flux (i.e., a set point, which may be, for example, a historical value or an optimized heat flux based on a prior iteration of block 404, or another predetermined value) by adjusting air flow through the vents. Moreover, in some implementations, the controller module 240 may have a power saving mode where the objective is to maintain the measured heat flux of each chassis vent 210, 212, 214 at or above a target heat flux, and, in response to a chassis vent 210, 212, or 214 having a measured heat flux less than the target heat flux, the controller module 240 reduces a speed of (or shuts off) at least one fan 220, 222, or 224 that produces air flow through that chassis vent having a measured heat flux greater than the target heat flux. For example, the measured heat flux of a vent may be greater than the target heat flux owing to a decrease in temperature of the air outside that vent, which increases natural convective flow of heated air from inside the chassis through that vent. Thus, by virtue of the power saving mode, the controller module 240 may account for environmental changes that affect ventilation and cooling of the device 200.

At block 406, at least one fan 220, 222, or 224 in an air flow path of at least one chassis vent of the plurality of chassis vents 220, 222, 224 is controlled according to the fan control signal. For example, in some implementations, each fan 214, 224, 234 may be in an air flow path of a respective chassis vent 220, 222, 224 on a one-to-one basis, as described above, and the controller module 240 may transmit the fan control signal generated at block 404 to each fan 214, 224, 234, so as to independently adjust air flow through the respective chassis vent 220, 222, 224. In some implementations, independently-controlled dampers in air flow paths of respective chassis vents 220, 222, 224 may be controlled by the fan control signal, so as to independently adjust air flow through each chassis vent 220, 222, 224.

After block 406, the method 400 can end. In some implementations, blocks 402, 404, and/or 406 are ongoing and recurring, in order to perform the optimization and/or closed-loop control logic described herein.

FIG. 5 is a flow diagram of a method 500 for generating a fan control signal according to an example implementation. In some implementations, the method 500 may be implemented, at least in part, in the form of executable instructions stored on a machine-readable medium and/or in the form of electronic circuitry. In some implementations, the steps of method 500 may be executed substantially concurrently or in a different order than shown in FIG. 5.

In some implementations, method 500 may include more or less steps than are shown in FIG. 5. In some implementations, one or more of the steps of method 500 may, at certain times, be ongoing and/or may repeat. Although execution of the method 500 is described below with reference to system 200, it should be understood that at least portions of method 500 may be performed by any other suitable device or system, such as, for example, the system 100 of FIG. 1.

The method starts, and at block 502, at least one heat flux sensor 230, 232, 234 measures a heat flux of each chassis vent of a plurality of chassis vents 210, 212, 214. In some implementations, the heat flux of each chassis vent 210, 212, 214 is measured by a corresponding heat flux sensor of a plurality of heat flux sensors 230, 232, 234. Block 502 may be analogous in many respects to block 402.

At block 504, the controller module 240 may calculate a total system heat flux based on the measured heat flux of each chassis vent 210, 212, 214. In some implementations, the total system heat flux may be a sum of the measured heat flux of each chassis vent 210, 212, 214.

At block 506, the orientation sensor module 250 may detect an orientation of the chassis 202, in which the plurality of chassis vents 210, 212, 214 are disposed, using, for example, an accelerometer, a magnetometer, a gyroscope, and/or the like included with the orientation sensor module 250. In some implementations, the detected orientation may be a portrait orientation or a landscape orientation. In some implementations, the detected orientation may be angular orientation in three dimensions.

At block 508, the orientation sensor module 250 may determine a convection pattern correlated with the orientation. For example, in some implementations, the orientation sensor module 250 may identify a convection pattern correlated with the orientation of the chassis 202 from convection patterns stored in a machine-readable medium of the device 200 (e.g., attached to the orientation sensor module 250). In some implementations, the orientation sensor module 250 may calculate a convection pattern correlated to the orientation based on a convection model. In some implementations, the convection pattern may include initial settings of fan speed and/or air flow direction for at least one of the fans 220, 222, 224, and/or a target heat flux of at least one of the vents 210, 212, 214, for use in block 516 described below. In some implementations, the orientation sensor module 250 may send the convection pattern to the controller module 240.

At block 510, the user hold detector module 270 may detect a user holding position on the chassis 202. As described above, in some implementations, the user hold detector module 270 may detect, using a resistive touch sensor, an infrared sensor, a pressure sensor, and/or the like in a vicinity of each of the chassis vents 210, 212, 214, whether a user holding position (e.g., where the user is holding the device 200) is in a vicinity of any of the chassis vents 210, 212, 214. In some implementations, the user hold detector module 270 may also send an indication of the user holding position (e.g., the identity of vent(s) where the user is holding the device 200) to the controller module 240.

At block 514, the temperature sensor module 260 may measure a temperature of the chassis 202 in which the plurality of chassis vents 210, 212, 214 are disposed. In some implementations, the temperature sensor module 260 may also send the temperature to the controller module 240.

At block 516, the controller module 240 may generate a fan control signal to adjust air flow through each chassis vent 210, 212, 214 independently, based on the measured heat flux of each chassis vent 210, 212, 214, and, in some implementations, further based on at least one of (that is, any combination of): the total system heat flux calculated at block 504, the convection pattern determined at block 508, the orientation detected at block 506, the user holding position detected at block 510, or the temperature measured at block 514. In some implementations, the controller module 240 may perform block 516 using optimization logic and/or closed-loop control logic to achieve (or attempt to achieve) any of the objectives described above with respect to block 404.

Additionally, the use of optimization logic and/or closed-loop control logic at block 516 may be modified by the total system heat flux, the convection pattern, the orientation, the user holding position, or the temperature, to achieve (or attempt to achieve) other objectives, as will be described below.

In some implementations, the controller module 240 may use optimization logic and/or closed-loop control logic to adjust air flow in order to maintain the total system heat flux at no lower than a set point (e.g., a historical set point, predetermined set point, or the like). At the same time as maintaining the total system heat flux, in some implementations, the controller module 240 may attempt to maximize the measured heat flux of each chassis vent 210, 212, 214 independently and/or may attempt to minimize power usage of each fan 214, 224, 234 independently. In some implementations, the controller module 240 may prioritize maintaining the total system heat flux over objectives related to the measured heat flux and fan power usage. In some implementations, the total system heat flux may be used as a substitute for the measured heat flux of each chassis vent 210, 212, 214, by virtue of the total system heat flux being calculated from the measured heat flux of each chassis vent 210, 212, 214.

In some implementations, the controller module 240 may receive (or retrieve) the orientation detected at block 506 and/or the convection pattern determined at block 508. As described above, the convection pattern may include (and the orientation may be correlated with) initial settings of fan speed and/or air flow direction for at least one of the fans 220, 222, 224, and/or a target heat flux of at least one of the chassis vents 210, 212, 214 (which may also be used to calculate a target total system heat flux). The controller module 240 may use the initial settings or the target heat flux in the optimization logic and/or closed-loop control logic to, for example, optimize measured heat flux at each vent 210, 212, 214. For example, in the example illustrated in FIGS. 3A and 3B, the convection pattern may provide an outward airflow for the fan 210 when the chassis 202 is detected to be in a landscape orientation (FIG. 3A) and an inward airflow for the fan 210 when the chassis 202 is detected to be in a portrait orientation (FIG. 3B).

In some implementations, the controller module 240 may receive (or retrieve) the user holding position detected at block 510. In some implementations, in response to the user holding position indicating that the device 200 is being held by a user in the vicinity of a chassis vent 210, 212, or 214, the controller module 240 may deem that vent to be potentially blocked by the user holding position. In response to the potentially blocked vent, the controller module 240 may ignore the measured heat flux of the potentially blocked vent when using optimization logic and/or closed-loop control logic to adjust air flow, and, in some implementations, the controller module 240 may reduce the speed of a fan in the air flow path of the potentially blocked vent to reduce fan power usage if the controller module 240 is unable to maintain the measured heat flux of the potentially blocked vent at a corresponding target heat flux. In some implementations, the controller module 240 may respond to a potentially blocked vent by increasing the target heat flux for unblocked vents and/or may attempt to maintain the total system heat flux (omitting the measured heat flux of the potentially blocked vent) at a target total system heat flux instead of maintaining the measured heat flux of each chassis vent 210, 212, 214.

In some implementations, the controller module 240 may receive (or retrieve) the temperature measured at block 514. In some implementations, the controller module 240 may use optimization logic and/or closed-loop control logic to adjust air flow in order to minimize the temperature or maintain the temperature at a set point, while simultaneously maximizing or maintaining the measured heat flux of each chassis vent 210, 212, 214. In some implementations, the temperature controller module 240 prioritizes minimizing or maintaining temperature over the maintaining the measured heat flux of each chassis vent 210, 212, 214.

At block 518, the method 500 may control at least one fan 220, 222, or 224 in an air flow path of at least one chassis vent 210, 212, 214 of the plurality of chassis vents 220, 222, 224 according to the fan control signal. Block 518 may be analogous in many regards to block 406. After block 518, method 500 can end. In some implementations, method 500 can be ongoing and recurring, in order to perform the optimization and/or closed-loop control logic described herein.

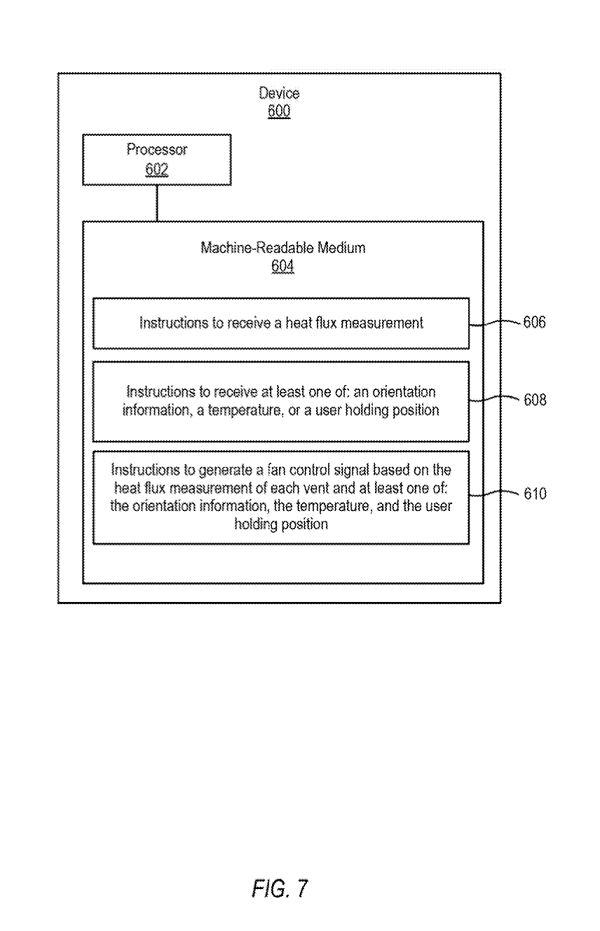

FIG. 6 is a block diagram illustrating a system 600 that includes a machine-readable medium encoded with instructions to generate a fan control signal according to an example implementation. In some example implementations, the system 600 may form part of a laptop computer, a desktop computer, a workstation, a mobile phone, a tablet computing device, a wearable electronic device, a gaming device, and/or other electronic device.

In some implementations, the system 600 is a processor-based system and may include a processor 602 coupled to a machine-readable medium 604. The processor 602 may include a central processing unit, a multiple processing unit, a microprocessor, an application-specific integrated circuit, a field programmable gate array, and/or other hardware device suitable for retrieval and/or execution of instructions from the machine-readable medium 604 (e.g., instructions 606, 608, and 610) to perform the various functions discussed herein. Additionally or alternatively, the processor 602 may include electronic circuitry for performing the functionality described herein, including the functionality of instructions 606, 608, and/or 610.

The machine-readable medium 604 may be any medium suitable for storing executable instructions, such as random access memory (RAM), electrically erasable programmable read-only memory (EEPROM), flash memory, hard disk drives, optical discs, and the like. In some example implementations, the machine-readable medium 604 may be a non-transitory medium, where the term “non-transitory” does not encompass transitory propagating signals. As described further herein below, the machine-readable medium 504 may be encoded with a set of executable instructions 606, 608, and 610.

Instructions 606, when executed by the processor 602, may receive a heat flux measurement of each chassis vent of a plurality of chassis vents of a device from at least one heat flux sensor of the device. Instructions 608, when executed by the processor 602, may receive at least one of: an orientation information about the device by an orientation sensor module, a temperature of the device, or a user holding position of the device. Instructions 610, when executed by the processor 602, may generate a fan control signal to control at least one fan based on the heat flux measurement of each chassis vent and at least one of: the orientation information, the temperature, and the user holding position.

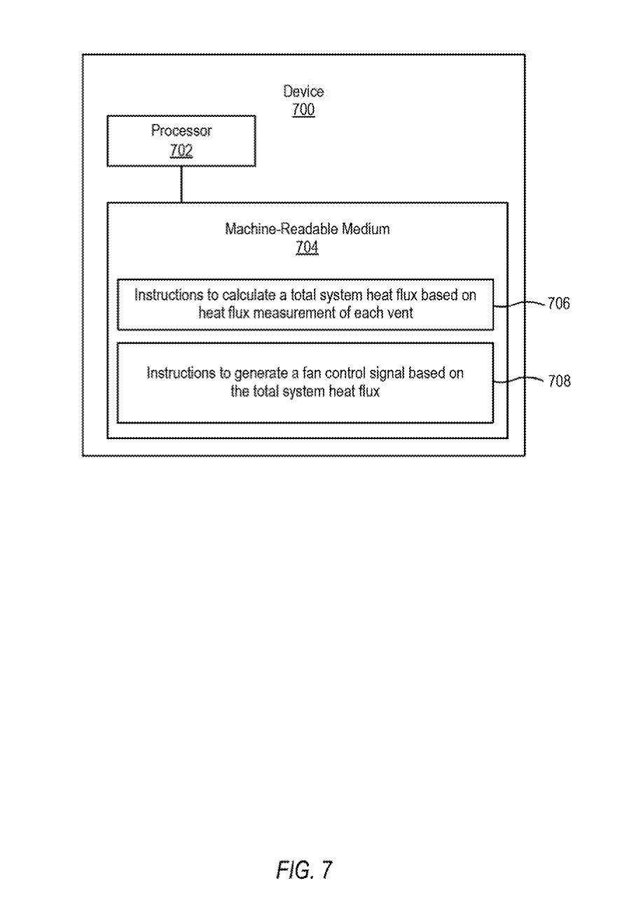

FIG. 7 is a block diagram illustrating a system 700 that includes a machine-readable medium encoded with instructions to generate a fan control signal according to an example implementation. In some example implementations, the system 700 may form part of a laptop computer, a desktop computer, a workstation, a mobile phone, a tablet computing device, a wearable electronic device, a gaming device, and/or other electronic device.

In some implementations, the system 700 is a processor-based system and may include a processor 702 coupled to a machine-readable medium 704. The processor 702 may include a central processing unit, a multiple processing unit, a microprocessor, an application-specific integrated circuit, a field programmable gate array, and/or other hardware device suitable for retrieval and/or execution of instructions from the machine-readable medium 704 (e.g., instructions 706 and 708) to perform the various functions discussed herein. Additionally or alternatively, the processor 702 may include electronic circuitry for performing the functionality described herein, including the functionality of instructions 706 and/or 708.

The machine-readable medium 704 may be any medium suitable for storing executable instructions, such as RAM, EEPROM, flash memory, hard disk drives, optical discs, and the like. In some example implementations, the machine-readable medium 704 may be a non-transitory medium, where the term “non-transitory” does not encompass transitory propagating signals. The machine-readable medium 704 may be encoded with a set of executable instructions 706 and 708. Instructions 706 may, when executed by the processor 702, calculate a total system heat flux based on a heat flux measurement of each chassis vent of a plurality of chassis vents of a device. In some implementations, the heat flux measurement of each chassis vent may be received by instructions 606. Instructions 708 may, when executed by the processor 702, generate a fan control signal based on the total system heat flux.

In view of the foregoing description, it may be appreciated that control of fans of a device may account for natural convective flow of heated air within the device to possibly improve heat dissipation efficiency. Moreover, it may be appreciated that control of the fans of the device may account for changes in the environment (e.g., cooler air outside the device), orientation of the device, and a user holding position on the device.

In the foregoing description, numerous details are set forth to provide an understanding of the subject matter disclosed herein. However, implementation may be practiced without some or all of these details. Other implementations may include modifications and variations from the details discussed above. It is intended that the following claims cover such modifications and variations.

We claim:

1. A device comprising:
a chassis having a plurality of vents;
a fan;
a heat flux sensor to measure a heat flux of the plurality of vents; and
a controller module to generate a fan control signal based on the measured heat flux of the plurality of vents, the fan control signal to control at least one of a fan speed or an air flow direction of the fan.

2. The device of claim 1, wherein
the heat flux sensor is one of a plurality of heat flux sensors,
at least one heat flux sensor of the plurality of heat flux sensors is disposed at each vent of the plurality of vents, so that the plurality of heat flux sensors measures a heat flux of each vent, and
the controller module is to generate the fan control signal further based on the measured heat flux of each vent.

3. The device of claim 2, wherein
the fan is one of a plurality of fans,
each vent of the plurality of vents is in an air flow path of at least one fan of the plurality of fans, and
the fan control signal is to control each fan of the plurality of fans independently.

4. The device of claim 1, further comprising at least one of:
an orientation sensor module to detect an orientation of the chassis, wherein the controller module is to generate the fan control signal further based on the orientation; or
a temperature sensor module to measure a temperature of the chassis, wherein the controller module is to generate the fan control signal further based on the temperature.

5. The device of claim 1, further comprising a user hold detector module to detect a user holding position, wherein the controller module is to generate the fan control signal further based on the detected user holding position.

6. The device of claim 1, wherein the controller module includes a power saving mode that generates a fan control signal to decrease the fan speed to reduce power usage when the measured heat flux of the plurality of vents is higher than a target heat flux.

7. The device of claim 5, wherein the fan control signal is to increase the fan speed when the measured heat flux of the plurality of vents is lower than a target heat flux and the detected user holding position is outside a proximity of the plurality of vents.

8. A method comprising:
measuring, by at least one heat flux sensor, a heat flux of each chassis vent of a plurality of chassis vents;
generating, by a controller module, a fan control signal to adjust air flow through each chassis vent independently, based on the measured heat flux of each chassis vent; and
controlling, according to the fan control signal, at least one fan in an air flow path of at least one chassis vent of the plurality of chassis vents.

9. The method of claim 8, further comprising calculating, by the controller module, a total system heat flux based on the measured heat flux of each chassis vent, wherein the generating the fan control signal is further based on the total system heat flux.

10. The method of claim 8, further comprising:
detecting, by an orientation sensor module, an orientation of a chassis in which the plurality of chassis vents are disposed; and
determining a convection pattern correlated with the convection pattern,
wherein the generating the fan control signal is further based on the convection pattern or the orientation.

11. The method of claim 8, further comprising detecting a user holding position on the chassis by a user hold detector module, wherein the generating the fan control signal is further based on whether the user holding position is in a vicinity of a chassis vent of the plurality of chassis vents.

12. The method of claim 9, further comprising measuring, by a temperature sensor module, a temperature of a chassis in which the plurality of chassis vents are disposed, wherein the generating the fan control signal is further based on the temperature.

13. The method of claim 8, wherein, in response to a chassis vent of the plurality of chassis vents having a measured heat flux greater than a target heat flux, the fan control signal is to reduce a fan speed of at least one fan in an air flow path of the chassis vent of the plurality of chassis vents having the measured heat flux greater than the target heat flux.

14. A non-transitory machine readable medium storing instructions executable by a processor of a device, the non-transitory machine readable medium comprising:
instructions to receive a heat flux measurement of each chassis vent of a plurality of chassis vents of the device, from at least one heat flux sensor of the device;
instructions to receive at least one of: an orientation information about the device by an orientation sensor module, a temperature of the device, or a user holding position of the device; and
instructions to generate a fan control signal to control at least one fan based on the heat flux measurement of each chassis vent of the plurality of chassis vents and at least one of: the orientation information, the temperature, and the user holding position.

15. The non-transitory machine readable medium of claim 14, further comprising:
instructions to calculate a total system heat flux based on the heat flux measurement of each chassis vent of the plurality of chassis vents; and
instructions to generate a fan control signal based on the total system heat flux.
